(19) United States
(12) Patent Application Publication
(10) Pub. No.: US 2020/0099129 A1
(43) Pub. Date: Mar. 26, 2020

(54) CHASSIS FOR ELECTRONIC DEVICE AND ELECTRONIC DEVICE

(71) Applicant: Fujitsu Client Computing Limited, Kanagawa (JP)

(72) Inventors: Kenji Suzuki, Kawasaki (JP); Daisuke Mihara, Kawasaki (JP)

(73) Assignee: Fujitsu Client Computing Limited, Kanagawa (JP)

(21) Appl. No.: 16/441,136

(22) Filed: Jun. 14, 2019

(30) Foreign Application Priority Data
Sep. 21, 2018 (JP) 2018-177421

(51) Int. Cl. H01Q 1/42; H05K 5/02; H01Q 1/24

(52) U.S. Cl. CPC H01Q 1/42; H01Q 1/24; H05K 5/0217

(57) ABSTRACT

A chassis for an electronic device includes a first member made of a first material and including a first part and a second part; a second member made of a second material different from the first material and including a first part and a second part; a projection disposed on one of the second part of the first member and the second part of the second member; and a receiver disposed in the other of the second part of the first member and the second part of the second member. The receiver defines an opening to contact with one end of the projection fitted in the opening in a second direction.

### CROSS-REFERENCE TO RELATED APPLICATIONS

This application claims priority from Japanese Patent Application No. 2018-177421 filed Sep. 21, 2018, the entire contents of which are incorporated herein by reference.

### FIELD

Embodiments described herein relate generally to a chassis for an electronic device and an electronic device.

### BACKGROUND

Conventionally, a chassis for an electronic device including a first part and a second part made of mutually different materials and joined together by insert molding is known.

It is difficult to improve the rigidity of such a chassis since the first part and the second part merely contact with each other but are not merged at the boundary, for example.

It is thus useful to provide a chassis for an electronic device which includes a first part and a second part made of mutually different materials and exerts an improved rigidity.

### SUMMARY

According to one embodiment, in general, a chassis for an electronic device includes a first wall with an end that extends in a first direction; a second wall that extends from the end of the first wall in a second direction crossing the first direction; a first member made of a first material, including a first part and a second part, the first part that forms a part of the first wall, the second part that forms a part of the second wall; a second member made of a second material different from the first material, including a first part and a second part, the first part that forms a part of the first wall and is joined to the first part of the first member, the second part that forms a part of the second wall and is adjacent to the second part of the first member in the first direction; a projection along the end of the first wall, provided on one of the second part of the first member and the second part of the second member; and a receiver provided in the other of the second part of the first member and the second part of the second member, the receiver that defines an opening into which the projection is fitted, and contacts with one end of the projection fitted in the opening in the second direction.

### BRIEF DESCRIPTION OF THE DRAWINGS

FIG. 1 is an exemplary perspective view illustrating the front side of an electronic device according to a first embodiment;

FIG. 2 is an exemplary exploded perspective view illustrating the front side of the electronic device according to the first embodiment;

FIG. 3 is an exemplary perspective view illustrating part of the front side of the electronic device with a front cover removed according to the first embodiment;

FIG. 4 is a section view of the electronic device taken along line IV-IV of FIG. 3;

FIG. 5 is an exemplary perspective view illustrating part of the front side of a rear cover according to the first embodiment;

FIG. 6 is a section view of the rear cover taken along line VI-VI of FIG. 5;

FIG. 7 is an exemplary perspective view illustrating part of the front side of a first member of the rear cover according to the first embodiment;

FIG. 8 is an exemplary perspective view illustrating an antenna unit according to the first embodiment; and

FIG. 9 is an exemplary section view illustrating part of a chassis of an electronic device according to a second embodiment.

### DETAILED DESCRIPTION

The following will disclose exemplary embodiments. Configurations of embodiments described below, and actions and effects implemented by the configurations are merely exemplary. Such embodiments are attainable by configurations other than those disclosed in the following embodiments. Such embodiments can attain one of various effects (including derivative effects) attained by the configurations.

The following embodiments include same or like elements. Same or like elements are denoted by common reference numerals, and redundant descriptions are omitted. In this disclosure, ordinal numbers are used to distinguish parts, members, regions, positions, directions, and the like, and are not intended to indicate order or priority.

### First Embodiment

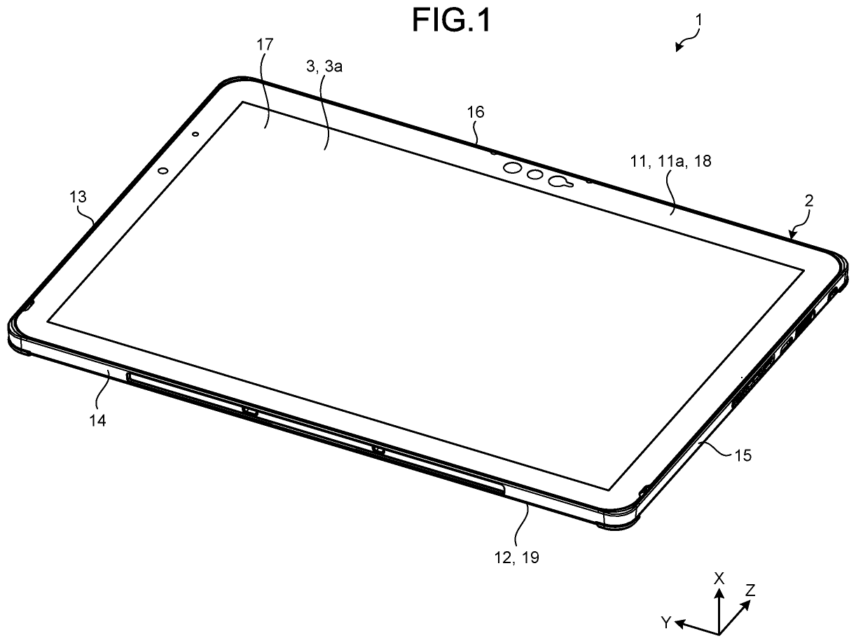

FIG. 1 is a perspective view illustrating the front side of an electronic device 1 according to a first embodiment. The electronic device 1 represents a tablet personal computer, for example. In the first embodiment, three directions orthogonal to one another are defined for convenience. X-direction is along the thickness (front-rear direction) of the electronic device 1, Y-direction is along the length (lateral direction) of the electronic device 1, and Z-direction is along the lateral side (vertical direction) of the electronic device 1. In the following, the X-direction is also referred to as frontward, a direction opposite the X-direction as rearward, the Y-direction as leftward, a direction opposite the Y-direction as rightward, the Z-direction as upward, and a direction opposite the Z-direction as downward. The electronic device 1 is not limited to the above example. The electronic device 1 may be a desktop personal computer, a clamshell (notebook) personal computer, a graphic display device, a television receiver, a game machine, a graphic display control device, or an information storage device, for example.

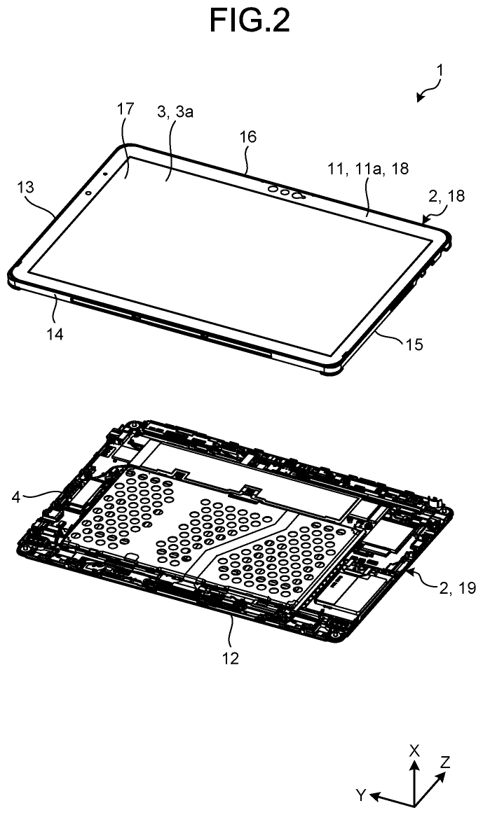

FIG. 2 is an exemplary exploded perspective view illustrating the front side of the electronic device 1 according to the first embodiment. As illustrated in FIG. 1 and FIG. 2, the electronic device 1 includes a chassis 2. The chassis 2 accommodates components such as a display unit 3 and an antenna unit 4 (FIG. 2).

The chassis 2 has a flat, approximately rectangular box shape. The chassis 2 includes a front wall 11 to which a display screen 3a of the display unit 3 is exposed, a rear wall 12 opposite the front wall 11, and a plurality of side walls 13 to 16 extending between the front wall 11 and the rear wall 12.

The front wall 11 has a rectangular frame shape. A front face 11a of the front wall 11 and the display screen 3a are covered by a transparent member 17. The front face 11a of the front wall 11 forms the front face of the chassis 2.

The rear wall 12 is spaced apart from the front wall 11 in the X-direction, and extends in a direction orthogonal to the X-direction (YZ-plane). The rear wall 12 has a quadrangular shape, specifically, a rectangular shape in front view.

Both of the side walls 13 and 15 extend in a direction orthogonal to the Y-direction (XZ-plane) and are substantially parallel to each other with spacing in the Y-direction. Both of the side walls 14 and 16 extend in a direction orthogonal to the Z direction (XY-plane), and are substantially parallel to each other with spacing in the Z-direction.

The chassis 2 includes a combination of a plurality of members including a front cover 18 and a rear cover 19. The front cover 18 includes the front wall 11 and part of each of the side walls 13 to 16. The rear cover 19 includes the rear wall 12 and part of each of the side walls 13 to 16. The front cover 18 and the rear cover 19 are joined together with pawls or screws, for example.

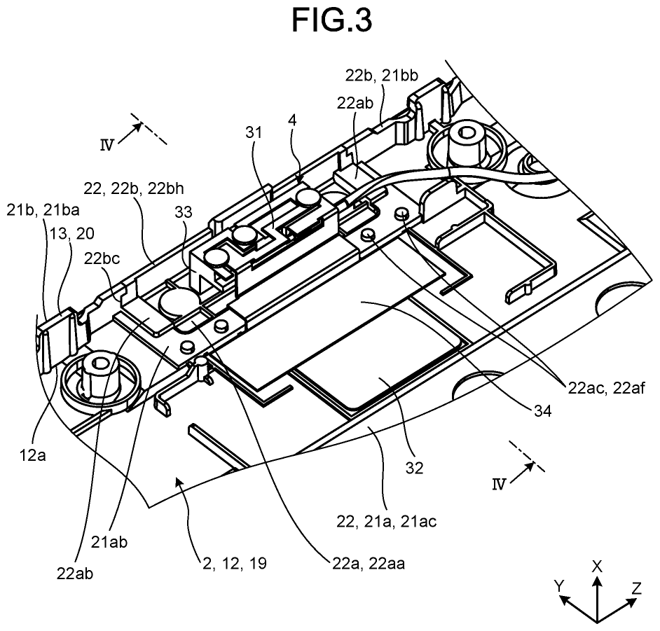

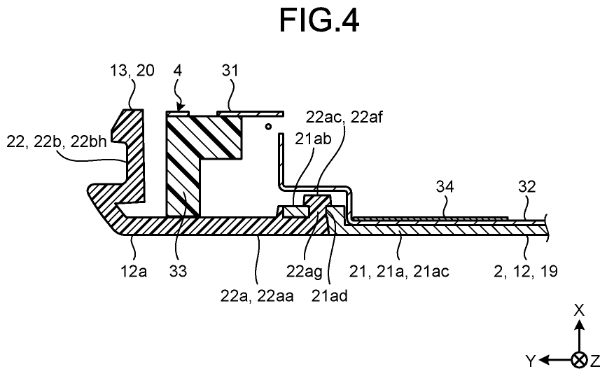

The following will describe the rear cover 19 in detail. FIG. 3 is an exemplary perspective view illustrating part of the front side of the electronic device 1 with the front cover 18 removed, according to the first embodiment. FIG. 4 is a section view of the electronic device 1 taken along line IV-IV of FIG. 3.

As illustrated in FIG. 3 and FIG. 4, the rear cover 19 includes a vertical wall 20 in addition to the rear wall 12. The antenna unit 4 is placed inside the rear wall 12 and the vertical wall 20.

The vertical wall 20 is connected to a Y-directional end 12a of the rear wall 12. The end 12a of the rear wall 12 extends in the Z-direction, and the vertical wall 20 extends in the X-direction from the end 12a. The vertical wall 20 forms part of the side wall 13. The rear wall 12 is an exemplary first wall, and the vertical wall 20 is an exemplary second wall. The Z-direction is an exemplary first direction, and the X-direction is an exemplary second direction crossing the first direction. The end 12a may be referred to as a side.

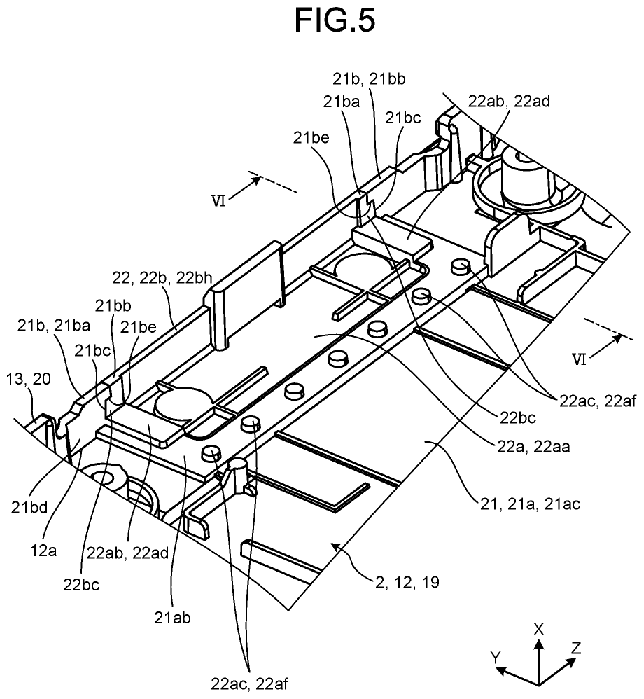

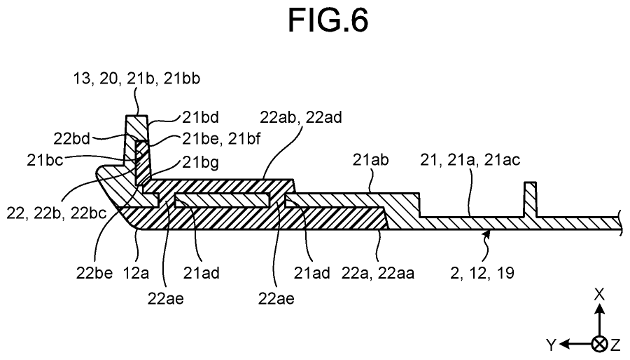

FIG. 5 is an exemplary perspective view illustrating part of the front side of the rear cover 19 according to the first embodiment. FIG. 6 is a section view of the rear cover 19 taken along line VI-VI of FIG. 5.

As illustrated in FIG. 5 and FIG. 6, the rear cover 19 includes a first member 21 and a second member 22. The first member 21 and the second member 22 are made of different materials from each other. The first member 21 is formed of a first material being a metal material such as a magnesium alloy while the second member 22 is formed of a second material being a synthetic resin material. The first member 21 and the second member 22 are manufactured by insert molding, for example.

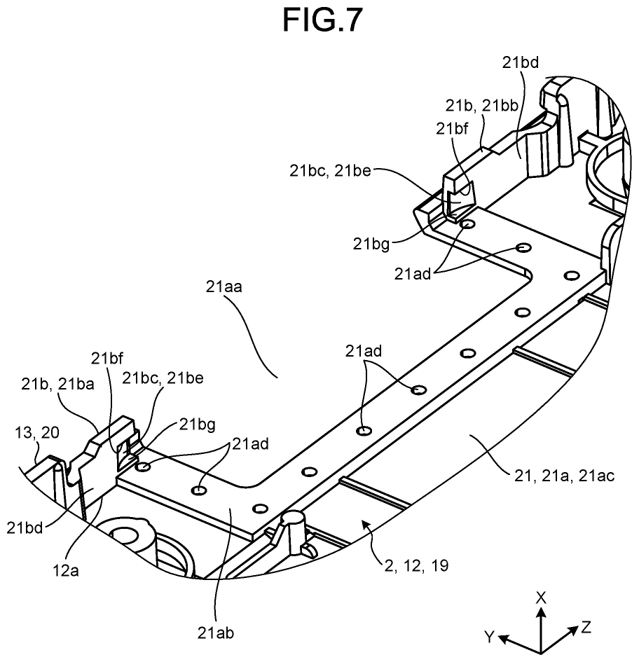

FIG. 7 is an exemplary perspective view illustrating part of the front side of the first member 21 of the rear cover 19 according to the first embodiment. As illustrated in FIG. 7, the first member 21 includes a first part 21a being part of the rear wall 12 and a second part 21b being part of the vertical wall 20. The first member 21 is provided with an opening 21aa between the first part 21a and the second part 21b. The opening 21aa is a cutout penetrating the first part 21a and the second part 21b in the X-direction.

The first part 21a includes a base 21ac and a joint 21ab connected to the base 21ac. The joint 21ab is located in the periphery of the opening 21aa. The joint 21ab is located further in the X-direction than the base 21ac. The first part 21a is provided with a step between the joint 21ab and the base 21ac. The joint 21ab is provided with through holes 21ad along the opening 21aa. The through holes 21ad penetrate the joint 21ab along the thickness of the rear wall 12.

The opening 21aa serves to divide the second part 21b of the first member 21 into two walls 21ba and 21bb. The wall 21bb is located in the Z-direction of the wall 21ba. In other words, the two second parts 21b are spaced apart from each other in the Z-direction. The walls 21ba and 21bb are each provided with a recess 21bc at the end on the opening 21aa side. The recesses 21bc are formed on inner faces 21bd of the walls 21ba and 21bb. The recess 21bc of the wall 21ba is open in a direction opposite to the Y-direction and in the Z-direction, while the recess 21bc of the other wall 21bb is open in the directions opposite to the Y-direction and the Z-direction. The first member 21 includes, on the walls 21ba and 21bb, depressed receivers 21be which define the recesses 21bc. In other words, the receivers 21be face the recesses 21bc. As illustrated in FIG. 6 and FIG. 7, each receiver 21be includes a pair of faces 21bf and 21bg spaced apart from each other in the X-direction. The faces 21bf and 21bg may cross a perpendicular of the rear wall 12. For example, the faces 21bf and 21bg are approximately parallel to the rear wall 12. The face 21bg is located in the direction opposite to the X-direction of the face 21bf. The recesses 21bc are an exemplary opening.

As illustrated in FIG. 5, the second member 22 includes a first part 22a being part of the rear wall 12 and a second part 22b being part of the vertical wall 20, to occlude the opening 21aa.

As illustrated in FIG. 4 to FIG. 6, the first part 22a is coupled to the first part 21a of the first member 21. The first part 22a includes a base 22aa, two connections 22ab, and a plurality of anchors 22ac. The base 22aa is juxtaposed to the joint 21ab of the first member 21 in the direction opposite the X-direction, to occlude the opening 21aa (FIG. 7) of the first member 21.

The first part 22a includes two connections 22ab at both Z-directional ends. As illustrated in FIG. 6, the connections 22ab each include a head 22ad and two shafts 22ae. The head 22ad is juxtaposed to the X-directional side of the joint 21ab. The two shafts 22ae are inserted into the through holes 21ad of the first member 21 to connect the head 22ad and the base 22aa. The head 22ad and the base 22aa are connected via the shafts 22ae to hold the joint 21ab in-between in the X-direction, that is, along the thickness of the rear wall 12.

As illustrated in FIG. 5, the anchors 22ac are aligned in the Z-direction with intervals on the opposite side of the opening 21aa in the Y-direction. As illustrated in FIG. 4, the anchors 22ac each include a head 22af and a shaft 22ag. The head 22af is juxtaposed to the X-directional side of the joint 21ab. The shaft 22ag is inserted to the through hole 21ad of the first member 21 to connect the head 22af and the base 22aa. The head 22af and the base 22aa, connected via the shaft 22ag, hold the joint 21ab in-between in the X-direction, that is, along the thickness of the rear wall 12.

As described above, in the first embodiment, the first part 22a of the second member 22 holds the first part 21a of the first member 21. Thereby, the first part 21a of the first member 21 and the first part 22a of the second member 22 are joined together.

As illustrated in FIG. 5, the second part 22b of the second member 22 is adjacent to the second part 21b of the first member 21. To be more specific, the second part 22b is located between the two walls 21ba and 21bb of the second part 21b of the first member 21 in contact with the two walls 21ba and 21bb. The second part 22b includes a base 22bh and two projections 22bc. The base 22bh extends in a direction orthogonal to the Y-direction (XZ-plane). Both Z-directional ends 22ba of the base 22bh are provided with the projections 22bc along the end 12a of the rear wall 12. The projections 22bc extend along the end 12a of the rear wall 12. Specifically, one projection 22bc projects from the end 22ba in the Z-direction and is fitted into the recess 21bc in the wall 21bb of the first member 21. The other projection 22bcprojects from the end 22bb in the direction opposite to the Z-direction and is fitted into the recess 21bc in the wall 21ba of the first member 21. The projections 22bc are also referred to as overhangs.

As illustrated in FIG. 6, one X-directional end 22bd of each projection 22bc is in contact with the face 21bf of the receiver 21be of the first member 21. The other end 22be of the projection 22bc is in contact with the face 21bg of the receiver 21be of the first member 21. That is, the pair of faces 21bf and 21bg of the receiver 21be holds the projection 22bc in-between.

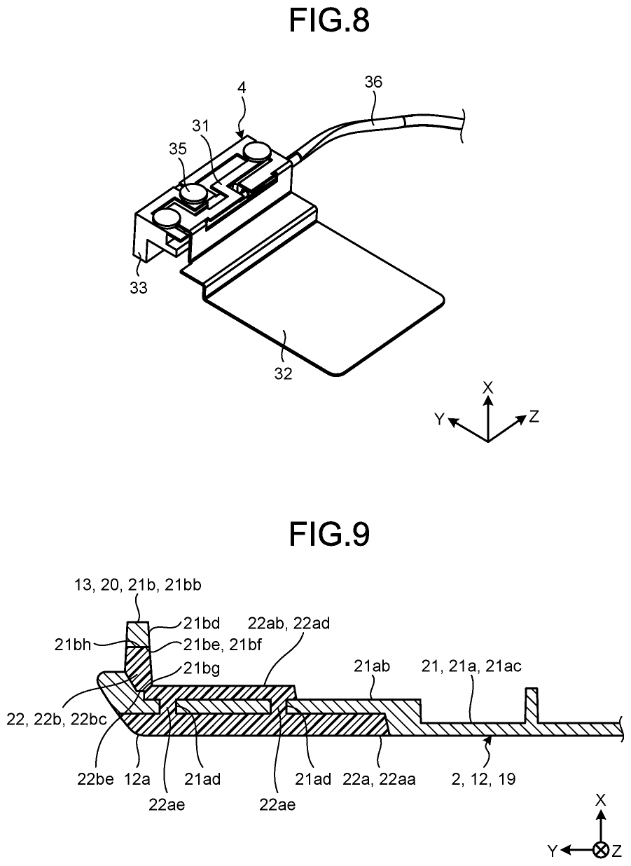

Next, the antenna unit 4 will be described in detail. FIG. 8 is an exemplary perspective view illustrating the antenna unit 4 according to the first embodiment. As illustrated in FIG. 8, the antenna unit 4 includes an antenna 31, an extension 32, and a support member 33. The antenna 31 is intended for wireless local area network (LAN), for example. The antenna 31 may be other antennas not in use for wireless LAN. The antenna 31 is made of a metal material. The antenna 31 is fixed to the support member 33 with a fastening member 35 such as a screw. The antenna 31 is connected to a circuit board through a cable 36. The support member 33 is made of a synthetic resin material. The extension 32 has a plate shape with a plurality of bends, and extends from the antenna 31. The extension 32 is made of a metal material. The extension 32 and the antenna 31 are formed of one sheet-metal member.

As illustrated in FIG. 3 and FIG. 4, the antenna 31 is placed inside the first part 22a of the second member 22 and the second part 22b of the second member 22. Due to the second member 22 made of a synthetic resin material, the antenna 31 can transmit and receive radio waves through the second member 22. The extension 32 is fixed to the base 21ac by a fixing member 34 in contact with the inner surface of the base 21ac of the first member 21. Thus, the antenna 31 and the first member 21 are electrically connected through the extension 32, and the first member 21 functions as a ground of the antenna 31. The fixing member 34 is sheet-like made of a metal material and is fixed to the base 21ac by adhesion, for example. The support member 33 is placed on the inner surface of the first part 22a of the second member 22.

As described above, in the first embodiment, the chassis 2 includes, along the end 12a of the rear wall 12 (first wall), the projections 22bc which are included in one (i.e., the second part 22b of the second member 22) of the second part 21b of the first member 21 and the second part 22b of the second member 22; and the receivers 21be which are included in the other (i.e., the second part 21b of the first member 21) of the second part 21b of the first member 21 and the second part 22b of the second member 22. The receivers 21be define the recesses 21bc (openings) into which the projections 22bc are fitted, and contact with the X-directional (second direction) ends 22bd of the projections 22bc fitted in the recesses 21bc. With such a configuration, for example, the contact between the ends 22bd of the projections 22bc and the receivers 21be can serve to improve the rigidity of the chassis 2 of the electronic device 1. Thus, if a bending force (X-directional force or opposite force) acts on the chassis 2 to move the side wall 14 and the side wall 16 relative to each other along the thickness of the chassis 2, the contact between the projections 22bc and the receivers 21be prevents the chassis 2 from being deformed. Thus, in the case of the chassis 2 having a coated outer surface, for example, it is possible to prevent stress concentration on the coating at the boundary between the first member 21 and the second member 22.

In the first embodiment, the receivers 21be each contact with both ends 22bd and 22be of the projection 22bc, for example. With such a configuration, the contact between the receivers 21be and both ends 22bd and 22be of the projections 22bc can work to improve the rigidity of the chassis 2 of the electronic device 1, as compared with the receivers 21be not in contact with the ends 22be of the projections 22bc.

Moreover, in the first embodiment, the inner face 21bd of the other (i.e., the second part 22b of the second member 22) of the second part 21b of the first member 21 and the second part 22b of the second member 22 is provided with the recesses 21bc, which are an exemplary opening. With such a configuration, the boundary between the projections 22bc and the receivers 21be can be prevented from being exposed to the outer face of the chassis 2, for example. This can lead to simplifying the structure of a metal mold for use in the insert molding of the first member 21 and the second member 22, for example.

Moreover, in the first embodiment, regarding the first part 21a of the first member 21 and the first part 22a of the second member 22, one (i.e., the first part 22a of the second member 22) holds the other (i.e., the first part 21a of the first member 21), for example. This eliminates the necessity for including a separate member such as screws to join the first part 21a of the first member 21 and the first part 22a of the second member 22, which can simplify the structure of the chassis 2.

### Second embodiment

FIG. 9 is an exemplary section view of part of a chassis 2 of an electronic device 1 according to a second embodiment. The second embodiment is different from the first embodiment mainly in that the first member 21 of the chassis 2 is provided with grooves 21bh instead of the recesses 21bc. The grooves 21bh penetrate the walls 21ba and 21bb of the second part 21b along the thickness (Y-direction) of the vertical wall 20. Thus, the projections 22bc of the second member 22 are fitted into the grooves 21bh and exposed to the outside of the chassis 2. FIG. 9 illustrates the wall 21bb of the walls 21ba and 21bb alone. The grooves 21bh are an exemplary opening.

The first and second embodiments have described the example that the second part 22b of the second member 22 is provided with the projections 22bc, and the second part 21b of the first member 21 is provided with the recesses 21bc or the grooves 21bh (opening). However, the present invention is not limited to such an example. The second part 21b of the first member 21 may be provided with the projections 22bc. The second part 22b of the second member 22 may be provided with the recesses 21bc or the grooves 21bh. The opening may be a hole with a bottom extending in the Z-direction or in the opposite direction.

The first and second embodiments have described the example that the first part 22a of the second member 22 holds the first part 21a of the first member 21. However, the present invention is not limited to such an example. The first part 21a of the first member 21 may hold the first part 22a of the second member 22.

Moreover, the second embodiment have described the example that the first member is made of the first material being a metal material, and the second member is made of the second material being a synthetic resin material. However, the present invention is not limited to such an example as long as the first material and the second material are different from each other. For example, the first material may be a synthetic resin material, and the second material may be a metal material. The first material and the second material may be different metal materials, for example. Alternatively, the first material and the second material may be different synthetic resin materials.

According to one aspect of this disclosure, for example, the chassis of the electronic device can be improved in rigidity due to the contact between one end of the projection and the receiver.

According to one aspect of this disclosure, for example, the chassis of the electronic device can be improved in rigidity due to the contact between both ends of the projection and the receiver, as compared with the receiver not in contact with one of the ends of the projection.

According to one aspect of this disclosure, for example, a metal mold for use in insert molding of the first member and the second member can be simplified in structure.

According to one aspect of this disclosure, for example, the first part of the first member and the first part of the second member can be joined together without a separate member such as a screw, which leads to simplifying chassis of the electronic device.

According to one aspect of this disclosure, for example, the electronic device including the above chassis exerts the same or similar effects as those of the chassis.

According to one aspect of this disclosure, for example, it is made possible to provide a chassis for an electronic device including a first part and a second part made of mutually different materials and exerting an improved rigidity.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions. In addition, specifications such as configurations and shapes (structure, kind, direction, form, size, length, width, thickness, height, number, arrangement, position, material, etc.) may be appropriately changed for implementation.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. A chassis for an electronic device, the chassis comprising:
a first wall with an end that extends in a first direction;
a second wall that extends from the end of the first wall in a second direction that crosses the first direction;
a first member made of a first material and that comprises a first part and a second part, wherein the first part forms a part of the first wall and the second part forms a part of the second wall;
a second member made of a second material different from the first material and that comprises a first part and a second part, wherein the first part forms a part of the first wall and is joined to the first part of the first member, the second part forms a part of the second wall and is adjacent to the second part of the first member in the first direction;
a projection along the end of the first wall, wherein the projection is disposed on one of the second part of the first member and the second part of the second member; and
a receiver disposed in the other of the second part of the first member and the second part of the second member, wherein the receiver defines an opening into which the projection is fitted, and contacts with one end of the projection fitted in the opening in the second direction.

2. The chassis for an electronic device according to claim 1, wherein
the receiver contacts the one end and an opposing end of the projection.

3. The chassis for an electronic device according to claim 1, wherein
the opening is a recess in an inner face of the other of the second part of the first member and the second part of the second member.

4. The chassis for an electronic device according to claim 1, wherein
one of the first part of the first member and the first part of the second member holds the other.

5. An electronic device comprising:
the chassis for an electronic device according to claim 1; and
an antenna that is disposed in the chassis, wherein
the first material is a metal material,
the second material is a synthetic resin material, and
the antenna is placed inside the first part of the second member and the second part of the second member.
